(19) United States
(12) Patent Application Publication
(10) Pub. No.: US 2017/0194511 A1
(43) Pub. Date: Jul. 6, 2017

(54) NON-VOLATILE MEMORY DEVICE AND METHOD FOR FABRICATING THE SAME

(71) Applicant: UNITED MICROELECTRONICS CORP., Hsinchu (TW)

(72) Inventors: Yu-Chun Chen, Kaohsiung City (TW); Chun-Hung Cheng, Kaohsiung City (TW); Yu-Chieh Lin, Kaohsiung City (TW); Ya-Sheng Feng, Tainan City (TW); Ping-Chia Shih, Tainan City (TW); Ling-Hsiu Chou, Tainan City (TW)

(21) Appl. No.: 15/007,280

(22) Filed: Jan. 27, 2016

(30) Foreign Application Priority Data
Jan. 5, 2016 (TW) 105100178

(51) Int. Cl. H01L 29/792; H01L 29/66

(52) U.S. Cl. CPC H01L 29/792; H01L 29/66833; H01L 29/6656

(57) ABSTRACT

A non-volatile memory (NVM) device includes a substrate, a charge trapping structure, a first gate electrode and a spacer. The charge trapping structure is disposed on the substrate. The first gate electrode is disposed on the charge trapping structure. The spacer is disposed on at least one sidewall of the first gate electrode and the charge trapping structure. Wherein, the charge trapping structure has a lateral size substantially greater than that of the first gate electrode.

This application claims the benefit of Taiwan application Serial No. 105100178, filed Jan. 5, 2016, the subject matter of which is incorporated herein by reference.

### BACKGROUND

Technical Field

The disclosure in generally relates to a semiconductor device and the method for fabricating the same, and more particularly to a non-volatile memory (NVM) device and the method for fabricating the same.

Description of the Related Art

NVM device which is able to continually store information even when the supply of electricity is removed from the device has been widespreadly adopted by bulk solid state memory applications.

To take an electrically-erasable programmable read-only memory (EEPROM) device having an oxide-nitride-oxide (ONO) structure for example, the EEPROM device includes a plurality of memory cells, each of which includes an ONO structure formed on a substrate, a control gate electrode formed on the ONO structure, a select gate electrode formed on a gate oxide and a source/drain structure formed in the substrate.

Typically, the profile of the ONO structure involved in each memory cell is defined by an etching process using the substrate as a stop layer. However, a portion of the substrate disposed between the control gate electrode and the select gate electrode and not covered by a photo-resist layer used to define the profile of the ONO structure may be over etched during the etching process. Non-uniform topography may occur on the surface of the substrate, and the non-uniform topography may deteriorate the uniformity of the ion implantations that are subsequently performed to form the source/drain structure of each memory cell in the substrate. Thus the threshold voltage (Vt) deviation of the memory cells may be increased, and leak may occurs within the program/erase operation of the EEPROM device.

Therefore, there is a need of providing an improved memory device and the method for fabricating the same to obviate the drawbacks encountered from the prior art.

### SUMMARY

One aspect of the present disclosure is to provide a NVM device includes a substrate, a charge trapping structure, a first gate electrode and a spacer. The charge trapping structure is disposed on the substrate. The first gate electrode is disposed on the charge trapping structure. The spacer is disposed on at least one sidewall of the first gate electrode and also disposed on the charge trapping structure. Wherein, the charge trapping structure has a lateral size substantially greater than that of the first gate electrode.

Another aspect of the present disclosure is to provide a method for fabricating an NVM device includes steps as follows: Firstly, a substrate is provided, and a charge trapping structure is then formed on the substrate. Next, a first gate electrode is formed on the charge trapping structure. Thereafter, an oxidation process is performed on the first gate electrode to form a spacer disposed on at least one sidewall of the first gate electrode and also disposed the charge trapping structure. Subsequently, an etching process is performed on the charge trapping structure using the first gate electrode and the spacer as an etching mask, so as to make the charge trapping structure having a lateral size substantially greater than that of the first gate electrode.

In accordance with the aforementioned embodiments of the present disclosure, an NVM device and the method for fabricating the same are disclosed. An ONO charge trapping structure is firstly formed on a substrate, and a control gate electrode is then defined on the ONO charge trapping structure. Next, an oxidation process is performed to form a spacer disposed on at least one sidewall of the control gate electrode and also to form a silicon oxide layer covering a portion of the substrate. Thereafter, an etching process is performed to remove a portion of the ONO charge trapping structure that is not covered by the spacer and the control gate. Subsequently, at least one ion implantation is performed using the spacer and the control gate electrode as a mask to form a light doped drain (LDD) region in the substrate and adjacent to the spacer and the control gate.

Since the etching process used to remove the portion of the ONO charge trapping structure is carried out by using the control gate electrode and the spacer which is disposed on at least one sidewall of the control gate, thus the lateral size of the remaining ONO charge trapping structure is substantially equal to the sum of the lateral size of the control gate electrode and the spacer. In other words, the ONO charge trapping structure has a lateral size substantially greater than that of the control gate. By this approach, the effective channel length of the control gate electrode can be elongated without increasing the entire size of the NVM device, whereby the Vt of the memory cells involved in the NVM device can be increased, and the leaking problems occurring within the program/erase operation can be mitigated.

In addition, because the oxidation process is performed prior to the etching process. The control gate electrode and the substrate can be protected by the silicon oxide layer formed by the oxidation process, wherein a portion of the silicon oxide layer can serve as the spacer used to prevent the poly-silicon control gate electrode from being damaged by the etching process, and the surface topography of the portion of the substrate covered by the silicon oxide layer can be remained uniform. As a result, the uniformity of the source/drain structure that is subsequently formed in the substrate by ion implantations can be improved, and the Vt deviation of the memory cells involved in the NVM device can be decreased.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIGS. 1A to 1H are cross-sectional views illustrating the processing structures for fabricating an NVM device having an ONO structure in accordance with one embodiment of the present invention.

### DETAILED DESCRIPTION

The embodiments as illustrated below provide a memory device and method for fabricating the same. The present invention will now be described more specifically with reference to the following embodiments illustrating the structure and arrangements thereof. It is to be noted that the following descriptions of preferred embodiments of this disclosure are presented herein for purpose of illustration and description only. It is not intended to be exhaustive or to be limited to the precise form disclosed. Also, it is also important to point out that there may be other features, elements, steps and parameters for implementing the embodiments of the present disclosure which are not specifically illustrated. Thus, the specification and the drawings are to be regard as an illustrative sense rather than a restrictive sense. Various modifications and similar arrangements may be provided by the persons skilled in the art within the spirit and scope of the present invention. In addition, the illustrations may not be necessarily be drawn to scale, and the identical elements of the embodiments are designated with the same reference numerals.

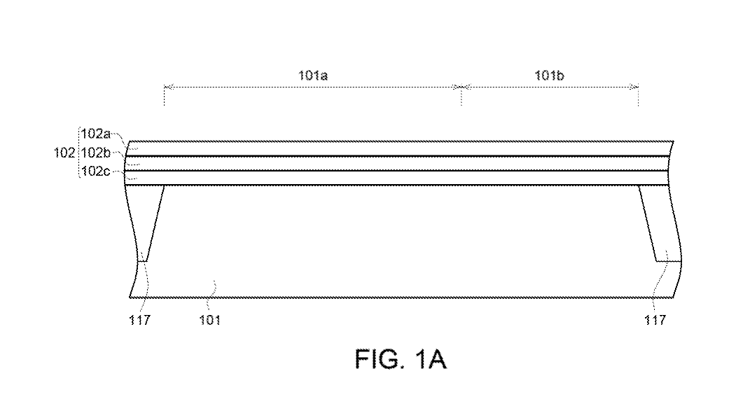

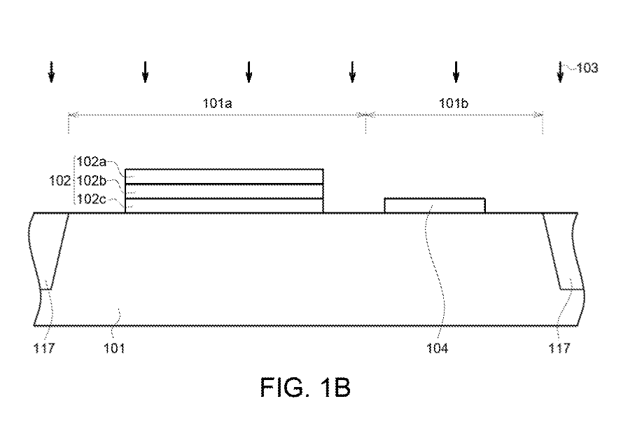

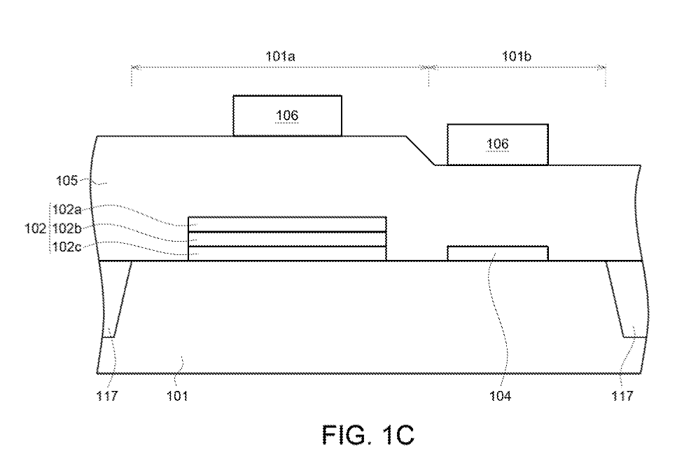

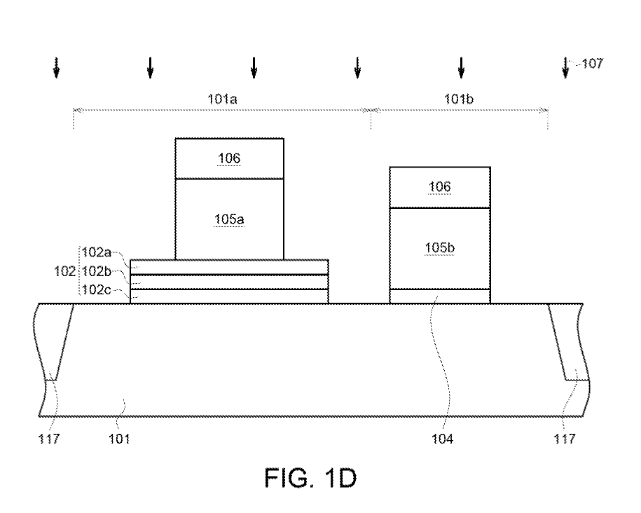

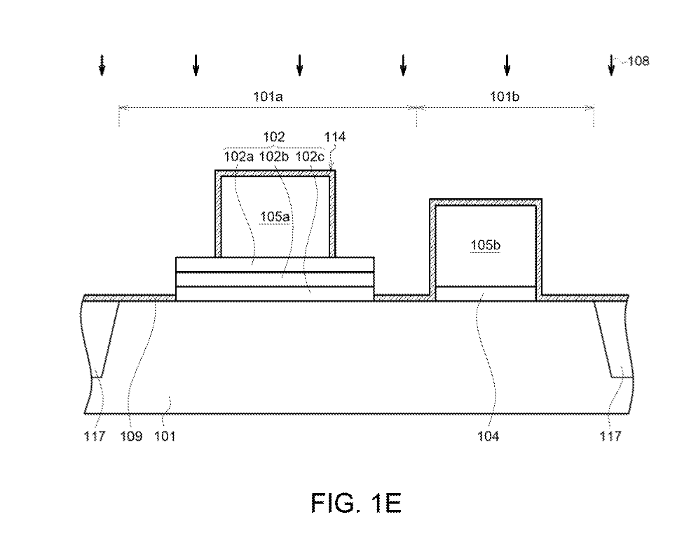

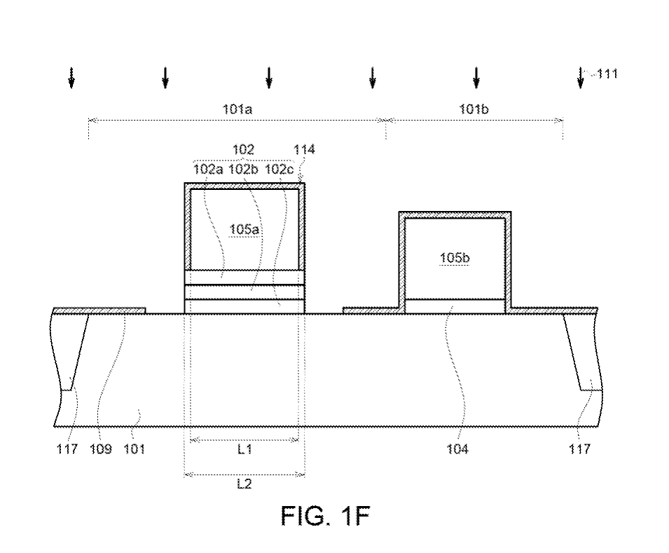

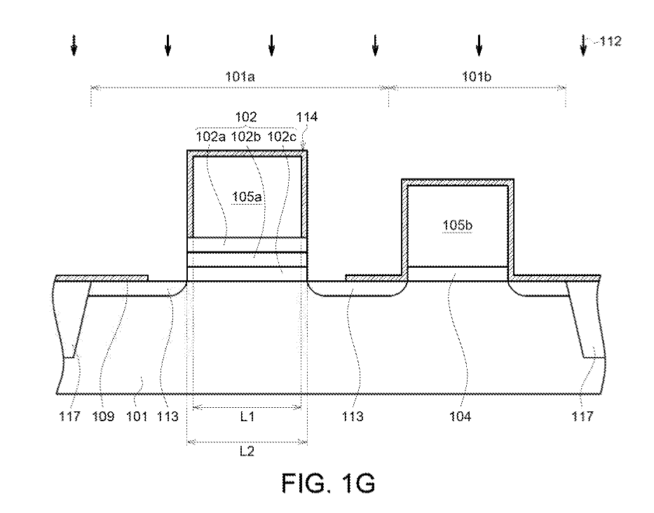

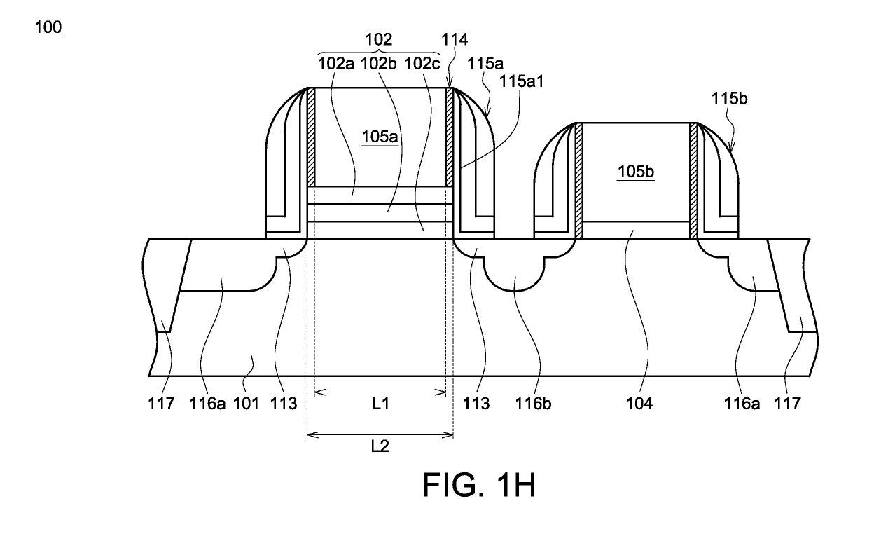

FIGS. 1A to 1H are cross-sectional views illustrating the processing structures for fabricating an NVM device 100 having an ONO structure in accordance with one embodiment of the present invention. In the present embodiment, the method for fabricating the NVM device 100 includes steps as follows:

Firstly, a substrate 101 is provided, and a charge trapping structure 102 is then formed on the substrate 101 (see FIG. 1A). In some embodiments of the present disclosure, the substrate 101 can be a semiconductor substrate made of semiconductor materials (such as silicon (Si), germanium (Ge), and so on), compound semiconductor materials (such as gallium arsenide (GaAs)). In some other embodiments, the substrate 101 can be a silicon-on-insulator (SOI) substrate.

In the present embodiment, the substrate 101 is a silicon wafer having a plurality of cell regions divided by a plurality of isolations structure 117, such as a plurality of shallow trench isolators (STIs), formed in the substrate 101. Each of the cell regions can be separated into a control gate area 101a and a select gate area 101b. For convenience of description, merely one single cell region including the control gate area 101a and the select gate area 101b is illustrated in FIG. 1A. However, it should be appreciated that the arrangement of the substrate 101 and cell regions is not limited to this regards.

The charge trapping structure 102 is a multi-layer composite structure at least including an upper silicon oxide layer 102a, a middle silicon nitride (SiN) layer 102b and a lower silicon oxide layer 102c. For example, in some embodiments of the present disclosure, the charge trapping structure 102 can be a multi-layer structure selected from a group consisting of an ONO structure, an oxide-nitride-oxide-nitride-oxide (ONONO) structure, a silicon-oxide-nitride-oxide-silicon (SONOS) structure, a bandgap engineered silicon-oxide-nitride-oxide-silicon (BE-SONOS) structure, a tantalum nitride, aluminum oxide, silicon nitride, silicon oxide, silicon (TANOS) structure and a metal-high-k bandgap-engineered silicon-oxide-nitride-oxide-silicon (MA BE-SONOS) structure.

Next, an etching process 103 is performed to remove the portion of the charge trapping structure 102 disposed in the select gate area 101b, so as to expose a portion of the substrate 101. A gate dielectric layer 104 is then formed on the portion of the substrate 101 in the select gate area 101b (see FIG. 1B). In some embodiments of the present disclosure, the etching process 103 used to remove the portion of the charge trapping structure 102 preferably is a dry etching process, such as a reactive ion etch (RIE) process. The gate dielectric layer 104 can be made of silicon-dioxide (SiO₂), SiN, silicon-oxynitride (SiNO), high dielectric constant (high-K) materials (e.g. hafnium oxide (HfO₂) and aluminum oxide (AlOₓ)) or the arbitrary combinations thereof.

Thereinafter, a poly-silicon layer 105 is formed on the substrate 101 to cover the control gate area 101a and the select gate area 101b. A patterned photo-resist layer 106 respectively aligning to the gate dielectric layer 104 and the remaining portion of the charge trapping structure 102 is then formed on the poly-silicon layer 105 (see FIG. 10). An etching process 107 is performed to remove portions of the poly-silicon layer 105, so as to form a control gate electrode 105a on the remaining portion of the charge trapping structure 102, to form a select gate electrode 105b on the gate dielectric layer 104, and to expose a portion of the substrate 101 again (see FIG. 1D).

After the patterned photo-resist layer 106 is peeled, a thermal oxidation process 108 is performed to form a silicon oxide layer 109 covering on the exposed portion of the substrate 101 and further covering on the sidewalls and top surfaces of the control gate electrode 105a and the select gate electrode 105b. In some embodiments of the present disclosure, the silicon oxide layer 109 can be formed by (but not limited to) a biased plasma oxidation process.

As shown in FIG. 1E the portion of the silicon oxide layer 109 disposed on the sidewalls of the control gate electrode 105a can serve as a spacer (hereinafter designated by the reference number 114). In some embodiments of the present disclosure, the spacer 114 that is disposed on one single side of the control gate electrode 105a preferably has a lateral width substantially ranging from 5 angstrom (Å) to 30 Å. The control gate electrode 105a preferably has a lateral width substantially ranging from 10 Å to 40 Å without counting the lateral widths of the spacers 114 dispose on the opposite sides thereof.

Subsequently, an etching process 111 is performed using the silicon oxide layer 109, the control gate electrode 105a and the spacers 114 as an etching mask to remove the portion of the charge trapping structure 102 not covered by the control gate electrode 105a and the spacers 114 (see FIG. 1F).

Since the remaining portion of the charge trapping structure 102 is covered by the control gate electrode 105a and the spacers 114 during the etching process 111, thus the lateral size L1 of the remaining portion of the charge trapping structure 102 is substantially equal to the sum of the lateral size of the control gate electrode 105a and the spacers 114. In other words, the remaining portion of the charge trapping structure 102 has a lateral size L1 substantially greater than the lateral size L2 of the control gate electrode 105a. In some embodiments of the present disclosure, the difference between the lateral size L1 of the remaining portion of the charge trapping structure 102 and the lateral size L2 of the control gate electrode 105a may substantially range from 5 Å to 30 Å.

An LDD ion implantation process 112 is then performed using the spacers 114 and the control gate electrode 105a as a mask to form an LDD region 113 in the substrate 101 and adjacent to the spacers 114 and the control gate 105a (see FIG. 1G).

After a series of deposition and etching processes (not shown) are carried out, a spacer 115a is formed on (the spacers 114 disposed over) the sidewalls of the control gate electrode 105a; and a spacer 115b is formed on the sidewalls of the select gate electrode 105b. Subsequently, a source/drain structure 116a/116b is formed in the substrate 101 by a plurality of ion implantation processes (not shown) using the control gate electrode 105a, the select gate electrode 105b and the spacers 115a/115b as a mask, meanwhile the process for forming the the NVM device 100 as shown in FIG. H is accomplished.

In the present embodiment, the spacers 115a has an L-shaped structure and is disposed on the outer surface of the spacer 114 separated from the control gate electrode 105a. For example, in some embodiment, the L-shaped structure may also have an ONO structure. The control gate electrode 105a and the select gate electrode 105b are disposed adjacent to a common source 116b. Since the processes for forming the spacers 115a/115b and the source/drain structure 116a/116b are well known, thus the materials and steps for forming the same are not redundantly described.

Because, the silicon oxide layer 109 formed by the thermal oxidation process 108 can cover the exposed portion of the substrate 101, the control gate electrode 105a and the select gate electrode 105b to prevent the exposed portion of the substrate 101, the control gate electrode 105a and the select gate electrode 105b from being damaged by the subsequent etching process 111, and the silicon oxide layer 109 can repair the non-uniform topography of the exposed portion of the substrate 101 resulted from the over etch of the etching process 103. The ion implantation processes for forming the source/drain structure 116a/116b thus can be subsequently performed on a relatively uniform surface. Such that, robustness or reliability of the ion implantation processes can be improved, and the threshold voltage (Vt) deviation of the memory cells involves in the NVM device 100 can be decreased.

In accordance with the aforementioned embodiments of the present disclosure, an NVM device and the method for fabricating the same are disclosed. An ONO charge trapping structure is firstly formed on a substrate, and a control gate electrode is then defined on the ONO charge trapping structure. Next, an oxidation process is performed to form a spacer disposed on at least one sidewall of the control gate electrode and also to form a silicon oxide layer covering a portion of the substrate. Thereafter, an etching process is performed to remove a portion of the ONO charge trapping structure that is not covered by the spacer and the control gate. Subsequently, at least one ion implantation is performed using the spacer and the control gate electrode as a mask to form an LDD region in the substrate and adjacent to the spacer and the control gate.

Since the etching process used to remove the portion of the ONO charge trapping structure is carried out by using the control gate electrode and the spacer which is disposed on at least one sidewall of the control gate, thus the lateral size of the remaining ONO charge trapping structure is substantially equal to the sum of the lateral size of the control gate electrode and the spacer. In other words, the ONO charge trapping structure has a lateral size substantially greater than that of the control gate. By this approach, the effective channel length of the control gate electrode can be elongated without increasing the entire size of the NVM device, whereby the Vt of the memory cells involved in the NVM device can be increased, and the leaking problems occurring within the program/erase operation can be mitigated.

In addition, because the oxidation process is performed prior to the etching process. The control gate electrode and the substrate can be protected by the silicon oxide layer formed by the oxidation process, wherein a portion of the silicon oxide layer can serve as the spacer used to prevent the poly-silicon control gate electrode from being damaged by the etching process, and the surface topography of the portion of the substrate covered by the silicon oxide layer can be remained uniform. As a result, the uniformity of the source/drain structure that is subsequently formed in the substrate by ion implantations can be improved, and the Vt deviation of the memory cells involved in the NVM device can be decreased.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A non-volatile memory (NVM) device, comprising:
a substrate;
a charge trapping structure, disposed on the substrate;
a first gate electrode, disposed on the charge trapping structure;
a spacer, disposed on and directly contacting to both of the first gate electrode and the charge trapping structure; and
an L-shaped spacer disposed on an outer surface of the spacer, separated from the first gate electrode and directly contacting to both of the spacer and the charge trapping structure;
wherein, the charge trapping structure has a lateral size substantially greater than that of the first gate electrode.

2. The NVM device according to claim 1, wherein the spacer has a lateral width substantially ranging from 5 angstrom (Å) to 30 Å, and the first gate electrode has a lateral width substantially ranging from 10 Å to 40 Å.

3. The NVM device according to claim 1, wherein the spacer comprises silicon oxide.

4. (canceled)

5. The NVM device according to claim 1, wherein the charge trapping structure is a multi-layer structure selected from a group consisting of an oxide-nitride-oxide (ONO) structure, an oxide-nitride-oxide-nitride-oxide (ONONO) structure, a silicon-oxide-nitride-oxide-silicon (SONOS) structure, a bandgap engineered silicon-oxide-nitride-oxide-silicon (BE-SONOS) structure, a tantalum nitride, aluminum oxide, silicon nitride, silicon oxide, silicon (TANOS) structure and a metal-high-k bandgap-engineered silicon-oxide-nitride-oxide-silicon (MA BE-SONOS) structure.

6. The NVM device according to claim 1, further comprising:
a gate dielectric layer, disposed on the substrate and adjacent to the charge trapping structure;
a second gate electrode, disposed on the gate dielectric layer; and
a common source, disposed in the substrate and between the first gate electrode and the second gate electrode.

7. A method for fabricating an NVM device, comprising:
providing a substrate;
forming a charge trapping structure on the substrate;
forming a first gate electrode on the charge trapping structure;
performing an oxidation process on the first gate electrode to form a spacer disposed on at least one sidewall of the first gate electrode and the charge trapping structure; and
performing an etching process on the charge trapping structure using the first gate electrode and the spacer as an etching mask, so as to make the charge trapping structure having a lateral size substantially greater than that of the first gate electrode.

8. The method according to claim 7, wherein the process for forming the charge trapping structure comprises steps of forming a multi-layer structure selected from a group consisting of an ONO structure, an ONONO structure, a SONOS structure, a BE-SONOS structure, a TANOS structure and a MA BE-SONOS structure on the substrate.

9. The method according to claim 7, wherein the process for forming a first gate electrode steps of:
forming a poly-silicon layer on the charge trapping structure;
forming a patterned photo-resist layer on the poly-silicon layer aligning to the charge trapping structure; and
etching the charge trapping structure by using the patterned photo-resist layer as an etching mask.

10. The method according to claim 7, wherein the etching process performed on the charge trapping structure is a dry etching process.

11. The method according to claim 10, further comprising an ion implantation process, after the dry etching process is carried out.

12. The method according to claim 11, further comprising steps for forming an L-shaped spacer disposed on an outer surface of the spacer separated from the first gate electrode, after the ion implantation process is carried out.

13. The method according to claim 7, wherein the spacer has a lateral width substantially ranging from 5 Å to 30 Å.

14. The method according to claim 7, further comprising:
forming a gate dielectric layer on the substrate and adjacent to the charge trapping structure;
forming a second gate electrode on the gate dielectric layer; and
performing at least one ion implantation process to form a common source in the substrate and between the first gate electrode and the second gate electrode.
